(19) United States
(12) Patent Application Publication
(10) Pub. No.: US 2024/0413102 A1
(43) Pub. Date: Dec. 12, 2024

(54) FORMING SHALLOW TRENCH FOR DICING AND STRUCTURES THEREOF

(71) Applicant: Taiwan Semiconductor Manufacturing co., Ltd., Hsinchu (TW)

(72) Inventors: Hung-Pin Chang, New Taipei City (TW); Cheng-Hsien Hsieh, Kaohsiung City (TW); Li-Han Hsu, Hsinchu (TW); Wei-Cheng Wu, Hsinchu (TW); Der-Chyang Yeh, Hsinchu (TW)

(21) Appl. No.: 18/462,499

(22) Filed: Sep. 7, 2023

Related U.S. Application Data
(60) Provisional application No. 63/507,150, filed on Jun. 9, 2023.

(51) Int. Cl. H01L 23/58; H01L 21/66; H01L 21/78; H01L 23/00; H01L 23/31

(52) U.S. Cl. CPC H01L 23/585; H01L 21/78; H01L 22/32; H01L 23/3121; H01L 24/08; H01L 2224/08225

(57) ABSTRACT

A method includes etching a portion of a wafer to form a first trench in a scribe line of the wafer, wherein the scribe line is between a first device die and a second device die of the wafer. After the etching, a top surface of the portion of wafer in the scribe line is underlying and exposed to the first trench, and the first trench is between opposing sidewalls of the wafer. A laser grooving process is then performed to form a second trench extending from the top surface further down into the wafer, and the second trench is laterally between the opposing sidewalls of the wafer. A die-saw process is then performed to saw the wafer. The die-saw process is performed from a bottom of the second trench, and the die-saw process results in the first device die to be separated from the second device die.

### PRIORITY CLAIM AND CROSS-REFERENCE

This application claims the benefit of the following provisionally filed U.S. patent application: Application No. 63/507,150, filed on Jun. 9, 2023, and entitled “Cost Effective Dummy for Hybrid Bonding-Extra Low K Integrity;” which application is hereby incorporated herein by reference.

### BACKGROUND

The packages of integrated circuits are becoming increasing complex, with more device dies integrated in the same package to achieve more functions. For example, packages may be formed to include a plurality of device dies such as processors and memory cubes in the same package. The packages can include device dies formed using different technologies and have different functions bonded to the same device die, thus forming a system. This may save manufacturing cost and achieve optimized device performance.

In a package, a top die may be bonded to a bottom die through bonding. The top die is a part of a wafer, which is sawed into a plurality of identical top dies. The bonding of the top die to the bottom die may be performed through one of a plurality of bond schemes such as solder bonding, direct metal-to-metal bonding, hybrid bonding (including both of dielectric-to-dielectric bonding and metal-to-metal bonding), or the like.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-7 illustrate the cross-sectional views of intermediate stages in the formation of a die and a respective package in accordance with some embodiments.

FIG. 8 illustrates a magnified view of a part of a die in accordance with some embodiments.

FIG. 9 illustrates a top view of a package in accordance with some embodiments.

FIG. 10 illustrates a wafer and the respective scribe lines, seal rings, and dummy conductive features in accordance with some embodiments.

FIG. 11 illustrates a process flow for forming a package in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A package including a top die bonding to a bottom package component and the method of forming the same are provided. In accordance with some embodiments of the present disclosure, a top wafer is formed to include a plurality of device dies separated from each other by scribe lines. An etching process is performed to form trenches in the scribe lines. In each of the scribe lines, there may be a single trench formed. The trench is shallow, and the etching is stopped before reaching a semiconductor substrate (such as a silicon substrate) of the wafer. A laser grooving process is performed in the trench, followed by a sawing process using a sawing blade. By forming one shallow trench instead of two deep trenches in a scribe line, the spaces needed for sawing is reduced, and more chip area may be left in the resulting device dies and outside of the seal ring. This may reduce delamination propagation.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

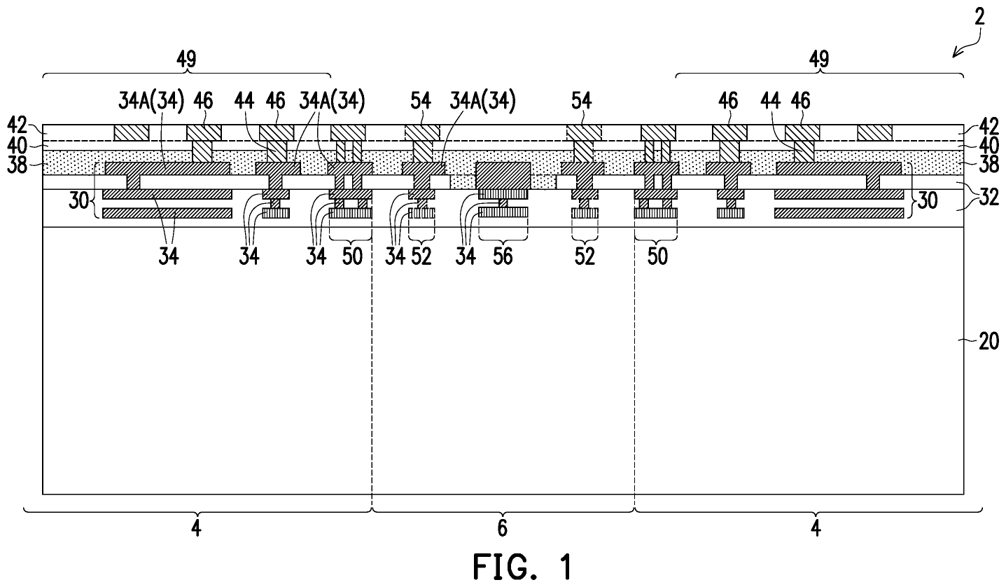

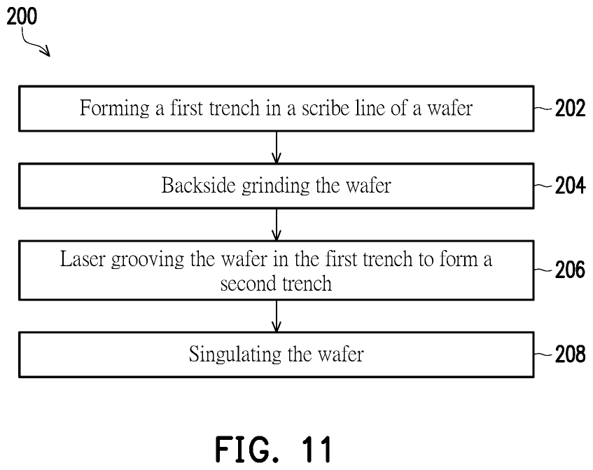

FIGS. 1 through 7 illustrate the cross-sectional views of intermediate stages in the formation of a package in accordance with some embodiments of the present disclosure. The corresponding processes are also reflected schematically in the process flow 200 as shown in FIG. 11.

FIG. 1 illustrates a cross-sectional view of package component 2 in accordance with some embodiments. In accordance with some embodiments, package component 2 is a device wafer including active devices such as transistors and/or diodes, and possibly passive devices such as capacitors, inductors, resistors, or the like. Package component 2 may include a plurality of device dies 4 therein, with the edge portions of two device dies 4 illustrated. Device dies 4 are alternatively referred to as chips hereinafter. In accordance with some embodiments, device die 4 is a memory die such as a Dynamic Random-Access Memory (DRAM) die or a Static Random-Access Memory (SRAM) die. Device die 4 may also be a logic die, which may be a Central Processing Unit (CPU) die, a Micro Control Unit (MCU) die, an input-output (IO) die, a BaseBand (BB) die, an Application processor (AP) die, or the like.

In accordance with some embodiments, wafer 2 includes semiconductor substrate 20 and the features formed at a top surface of semiconductor substrate 20. Semiconductor substrate 20 may be formed of crystalline silicon, crystalline germanium, crystalline silicon germanium, or the like. Semiconductor substrate 20 may also be a bulk silicon substrate or a Silicon-On-Insulator (SOI) substrate. Shallow Trench Isolation (STI) regions (not shown) may be formed in semiconductor substrate 20 to isolate the active regions in semiconductor substrate 20. Although not shown, through-vias may be (or may not be) formed to extend into semiconductor substrate 20, and the through-vias are used to electrically inter-couple the features on opposite sides of wafer 2.

In accordance with some embodiments, wafer 2 includes integrated circuit devices (not shown), which may be formed on the top surface of semiconductor substrate 20. Example integrated circuit devices may include Complementary Metal-Oxide Semiconductor (CMOS) transistors, resistors, capacitors, diodes, and/or the like. The details of the integrated circuit devices are not illustrated herein. In accordance with alternative embodiments, wafer 2 is used for forming interposers, which are free from active devices and passive devices.

An Inter-Layer Dielectric (ILD, one of dielectric layers 32) is formed over semiconductor substrate 20, and fills the space between the gate stacks of transistors (not shown) in the integrated circuit devices. In accordance with some embodiments, the ILD is formed of Phospho Silicate Glass (PSG), Boro Silicate Glass (BSG), Boron-Doped Phospho Silicate Glass (BPSG), Fluorine-Doped Silicate Glass (FSG), silicon oxide, or the like. the ILD may be formed using spin coating, Flowable Chemical Vapor Deposition (FCVD), Chemical Vapor Deposition (CVD), Plasma Enhanced Chemical Vapor Deposition (PECVD), Low Pressure Chemical Vapor Deposition (LPCVD), or the like.

Contact plugs (not shown) are formed in the ILD, and are used to electrically connect the integrated circuit devices to overlying metal lines and vias 34. In accordance with some embodiments, the contact plugs are formed of a conductive material selected from tungsten, aluminum, copper, titanium, tantalum, titanium nitride, tantalum nitride, alloys thereof, and/or multi-layers thereof. The formation of the contact plugs may include forming contact openings in the ILD, filling a conductive material(s) into the contact openings, and performing a planarization process (such as Chemical Mechanical Polish (CMP) process) to level the top surfaces of the contact plugs with the top surface of the ILD.

Interconnect structure 30 is formed over the integrated circuits. Interconnect structure 30 includes dielectric layers 32, which includes the ILD and the dielectric layers over the ILD. Interconnect structure 30 further includes metal lines and vias 34 formed in dielectric layers 32. The dielectric layers 32 over the ILD are alternatively referred to as Inter-Metal Dielectric (IMD) layers 32 hereinafter. In accordance with some embodiments, some lower ones of dielectric layers 32 are formed of a low-k dielectric material having a dielectric constant (k-value) lower than about 3.8, and may be lower than about 3.5 or about 3.0. The IMD hence may be extreme low-k dielectric layers. Dielectric layers 32 may be formed of a carbon-containing low-k dielectric material, Hydrogen SilsesQuioxane (HSQ), MethylSilsesQuioxane (MSQ), or the like. In accordance with alternative embodiments of the present disclosure, some or all of dielectric layers 32 are formed of non-low-k dielectric materials such as silicon oxide, silicon carbide (SiC), silicon carbo-nitride (SiCN), silicon oxy-carbo-nitride (SiOCN), or the like. Etch stop layers (not shown), which may be formed of silicon carbide, silicon nitride, aluminum oxide, aluminum nitride, or the like, or multi-layers thereof, may be formed between IMD layers 32, and are not shown for simplicity.

Metal lines and vias 34 are formed in dielectric layers 32. The metal lines 34 at a same level are collectively referred to as a metal layer hereinafter. In accordance with some embodiments, interconnect structure 30 includes a plurality of metal layers that are interconnected through vias. Metal lines and vias 34 may be formed through single damascene and/or dual damascene processes. Metal lines and vias 34 may include diffusion barriers and copper-containing metallic materials over the corresponding diffusion barriers. The diffusion barriers may include titanium, titanium nitride, tantalum, tantalum nitride, or the like.

Metal lines 34 include metal lines/pads 34A, which are sometimes referred to as top metal lines/pads. Top metal lines/pads 34A are also collectively referred to as being a top metal layer. The respective dielectric layer 38 may be formed of a non-low-k dielectric material such as Undoped Silicate Glass (USG), silicon oxide, silicon nitride, and/or the like.

In accordance with some embodiments, dielectric layer 40 is formed over the top metal layer. It is appreciated that the illustrated dielectric layers 38, 40, and 42 are examples, and the wafer 2 may include different materials and layers than illustrated. Dielectric layer 40 represents the possible dielectric layer(s) that may be adopted in wafer 2. In accordance with some embodiments, dielectric layer 40 is formed of or comprises an inorganic dielectric material such as silicon oxide, silicon oxynitride, silicon oxy-carbide, silicon oxy carbo-nitride, USG, or the like.

In accordance with some embodiments, dielectric layer 42 is formed as a top surface layer of wafer 2. Dielectric layer 42 may be used for fusion bonding, and hence is alternatively referred to as bond film 42 hereinafter. Bond film 42 may be deposited using Plasma-Enhanced Chemical Vapor Deposition (PECVD), Atomic Layer Deposition (ALD), High Density Plasma Chemical Vapor Deposition (HDPCVD), Plasma Enhanced ALD (PECVD), or the like. Bond film 42 may be formed of or comprise a silicon-containing dielectric material. In accordance with some embodiments, the material of bond film 42 may be expressed as SiOₓN_{y}C_{z}, with x being in the range between about 0 and about 2, y being in the range between about 0 and about 1.33, and z being in the range between about 0 and about 1. At least one or more of values x, y, and z is greater than zero. For example, bond film 42 may be formed of or comprises SiON, SiN, SiOCN, SiCN, SiOC, SiC, SiO₂, or the like. Bond film 42 may be formed of a dielectric material different from, or same as, the dielectric material of dielectric layer 40.

As also shown in FIG. 1, vias 44 and bond pads 46 are formed. In accordance with some embodiments, the formation process of vias 44 and bond pads 46 may include two single damascene process or a dual damascene process. The damascene process(es) may include etching dielectric layers 42 and 40 to form trenches and via openings, filling the trenches and via openings with a conformal barrier layer and a metallic material, and performing a planarization process such as a Chemical Mechanical Polish (CMP) process or a mechanical grinding process to remove excess portions of the barrier layer and the metallic material. The remaining portions of the barrier layer and the metallic material are vias 44 and bond pads 46. The top surfaces of bond pads 46 are thus coplanar with the top surface of bond film 42. In accordance with some embodiments, the barrier layer comprises Ti, TiN, Ta, TaN or the like. The metallic material may include copper.

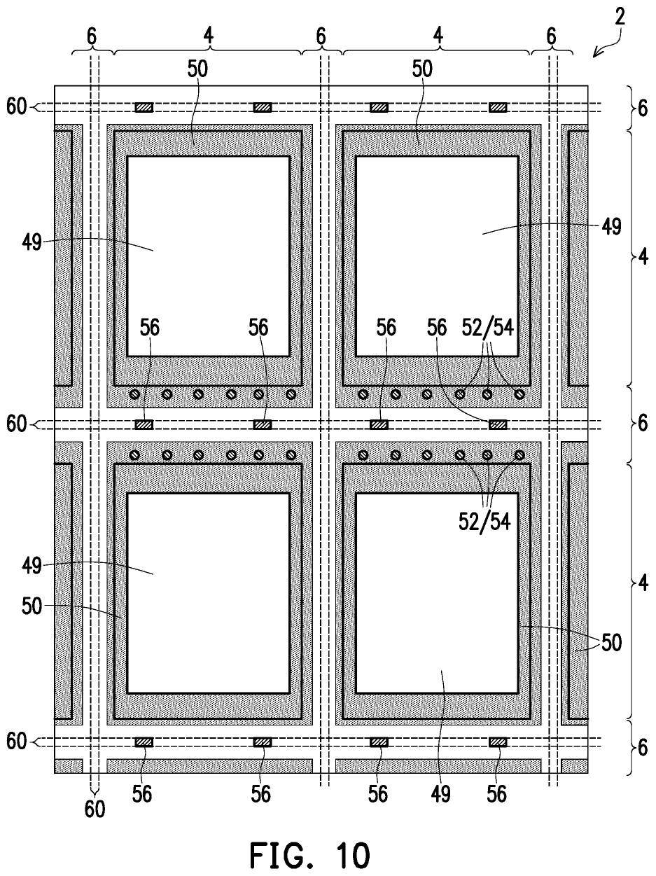

Referring to FIG. 10, which illustrates a top view of wafer 2, a plurality of device dies 4 are arranged as an array including a plurality of rows and columns. A plurality of scribe lines 6 are located between device dies 4. In accordance with some embodiments, seal rings 50 are formed to encircle the active areas 49 of the device dies 4. The active areas 49 are used to form functional integrated circuits (active devices and passive devices) and interconnect structures. Seal rings 50 may be formed as full rings, with no breaks therein in the top view. Before wafer 2 is singulated, the outer edges of seal rings 50 may be considered as the outer boundaries of the device dies 4. It is appreciated, however, that the subsequent die-saw process will leave some portions of scribe lines 6 outside of the seal rings of the discrete device dies 4. Accordingly, after the singulation process for sawing wafer 2 into discrete device dies 4, the discrete device dies 4 also include portions outside of the respective seal rings 50. The discrete device dies 4 generated by sawing wafer 2 are thus larger than the portions inside the outer edges of seal ring 50.

In accordance with some embodiments, each device die 4 may include a single seal ring. Alternatively, each device die 4 may include a plurality of seal rings, with outer seal ring(s) encircling the respective inner seal ring(s)s. When more than one seal ring is formed for each of device dies 4, the illustrated seal ring 50 is the outmost seal ring that is closest to the scribe lines.

Referring back to FIG. 1, seal ring 50 includes some contact plugs (not shown), and metal lines and vias 34. The contact plugs and metal lines and vias 34 are formed at the same time and share the same formation processes as the respective other contact plugs and the metal lines/vias 34 that are in active area 49. Each of the contact plugs and metal lines/vias 34 in seal ring 50 may form a full ring, which is physically joined with the overlying and underlying rings to form an integrated seal ring.

In accordance with some embodiments, seal rings 50 are electrically connected to semiconductor substrate 20 through the respective contact plugs. There may be (or may not be) silicide regions between and physically joining the contact plugs and semiconductor substrate 20. In accordance with alternative embodiments, the contact plugs are in physical contact with semiconductor substrate 20. In accordance with yet alternative embodiments, the contact plugs are spaced apart from semiconductor substrate 20 by a dielectric layer such as a contact etch stop layer (underlying the ILD), the ILD, and/or the like.

In accordance with some embodiments, dummy conductive features 52 are formed in scribe line 6, and outside of the seal rings 50 of device dies 4. In accordance with alternative embodiments, no dummy conductive features 52 are formed, and hence dummy conductive features 52 are illustrated as being dashed to indicate that these features may be or may not be formed. In accordance with some embodiments, dummy conductive features 52 are referred to as testing conductive features, which are used for testing the functionality of device dies. The testing may be performed by probing dummy conductive pads 54, which are the top surface features of dummy conductive features 52. The testing is performed before the subsequently discussed singulation process of wafer 2.

In accordance with some embodiments, there may be some dummy conductive features 56 formed in scribe lines 6, which conductive feature are also dummy features. In accordance with some embodiments, dummy conductive features 56 are formed at or close to the center of the respective scribe line 6. In accordance with some embodiments, as aforementioned, dummy conductive features 52 include dummy metal pads 54, whose top surfaces are coplanar with the top surface of bond film 42. The top surfaces of dummy conductive features 56, on the other hand, may be level with or lower than the bottom surface of bond film 42, and may be level with or lower than the top surface of lower surface of any underlying dielectric layer. Accordingly, between the bottom surface of bond film 42 and the topmost surfaces of dummy conductive features 56, there is one or more dielectric layer(s). Dummy conductive features 56 may be electrically connected to dummy conductive features 52, or may electrically decoupled from dummy conductive features 52.

Referring to FIG. 10 again, the top views of some example dummy conductive features 52 (including dummy conductive pads 54) and dummy conductive features 56 are illustrated. It is appreciated that although dummy conductive features 52 are illustrated as having rounded top-view shape and are separated from each other, and dummy conductive features 56 are illustrated as having rectangular top-view shapes, these features may have any top-view shape, and may be connected to each other or decoupled from each other in different combinations.

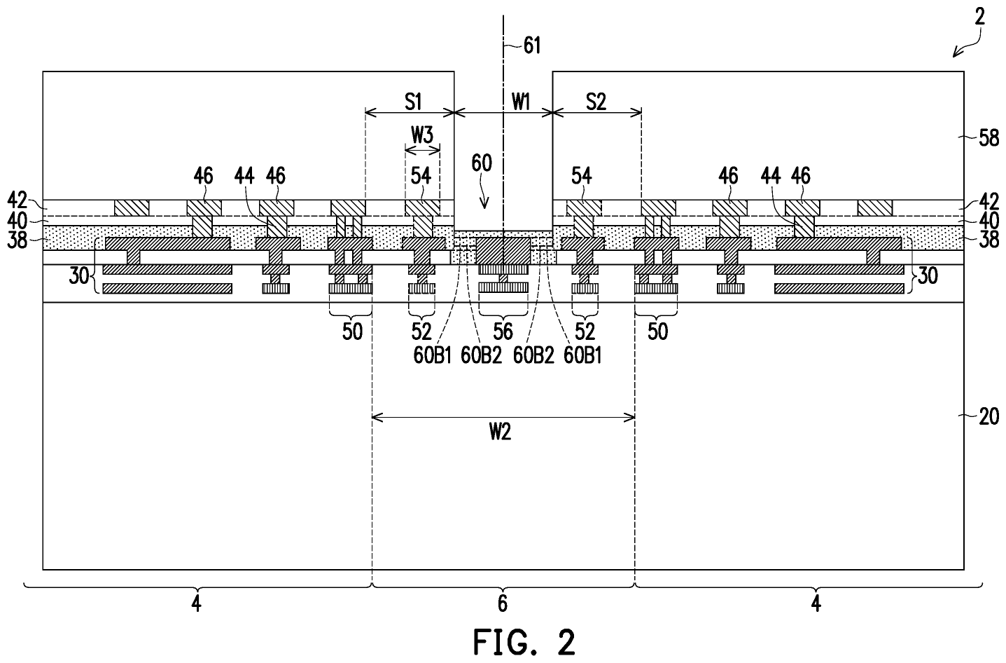

Referring to FIG. 2, etching mask 58 is formed and patterned, and trench 60 is formed in etching mask 58 to expose the underlying wafer 2. The respective process is illustrated as process 202 in the process flow 200 as shown in FIG. 11. The width W1 of trench 60 is smaller than the width W2 of the respective scribe line 6. In accordance with some embodiments, ratio W1/W2 is smaller than about 0.7, and may be smaller than about 0.5. Etching mask 58 may comprise a photoresist, and may or may not include an anti-reflective coating. Etching mask 58 may also be a single-layer etching mask, a double-layer etching mask, or a tri-layer etching mask.

The patterned etching mask 58 covers entireties of device dies 4, and further extend directly over (and overlap) some portions of scribe lines 6. In accordance with some embodiments in which dummy conductive features 52 are formed, etching mask 58 may cover some or all of dummy conductive features 52. Dummy conductive features 56 may be directly underlying trench 60.

An anisotropic etching process is then performed to etch wafer 2, so that trench 60 further extends down into the top portion of wafer 2. Bond film 42 is etched-through. In accordance with some embodiments, trench 60 extends to a same level of the bottom surface of bond film 42 (within process variation). In accordance with some embodiments, the etching includes a dry etching process, which may be a plasma etching process. In accordance with some embodiments, depending on the material of bond film 42 and dielectric layer 40, the etching gas may include the mixture of NF₃ and NH₃, the mixture of HF and NH₃, or gases such as CF₄, NF₃, SF₆, CHF₃, ClF₃, or combinations thereof. Other gases such as O₂, N₂, H₂, NO, and the like, may also be added. Sputtering gas such as argon may be added, so that some sputtering may be used to enhance the anisotropic effect.

In the etching process, dielectric layer 40 may be used as an etch stop layer in accordance with some embodiments when dielectric layer 40 is formed of a dielectric material that is different from the dielectric material of bond film 42. In accordance with some embodiments in which bond film 42 is formed of a same dielectric material as dielectric layer 40, or bond film 42 and dielectric layer 40 comprise different dielectric materials, but the difference is not adequate to result in enough etching selectivity, the etching may also be performed using a time mode to stop the etching.

The bottom of trench 60 is higher than the top surface of substrate 20. In accordance with some embodiments, the etching is stopped at a level higher than the topmost surface of dummy conductive features 56. Accordingly, a dielectric layer, which may be a remaining portion of dielectric layer 40, may be left over dummy conductive features 56 at the time the etching is stopped. In accordance with alternative embodiments, the etching is stopped at a time after the topmost surface of the dummy conductive features 56 is exposed. In the etching process, dummy conductive features 56 may not be etched. Accordingly, the bottom of trench 60 may also be level with (within process variation) or lower than the topmost surface of dummy conductive features 56, which possible bottoms of trench 60 are illustrated using dashed lines 60B1 and 60B2 in FIG. 2.

Also, as shown in FIG. 2, there is a single (rather than two) trench 60 in each scribe line 6. Trench 60 may cross the middle line 61, which is in the middle of scribe line 6 and has equal distances to the seal rings 50 in opposing device dies 4. Advantageously, with a single trench (rather than two trenches) being formed, the edges of trench 60 may be made farther away from seal rings 50 than if two trenches are formed. In accordance with some embodiments, spacings S1 and S2 between trench 60 and the nearest seal rings 50 are greater than the width W3 of dummy metal pads 54. Spacings S1 and S2 may be in the range between about 10% and about 90% of the width W2 of scribe line 6. In accordance with some embodiments, spacing S1 is equal to spacing S2. In accordance with alternative embodiments, spacing S1 is different from spacing S2. Making spacing S1 to be different from spacing S2 may advantageously suit to the packaging requirement, as discussed subsequently referring to FIG. 9.

In accordance with some embodiments, between dummy conductive features 56 and dummy conductive features 52, a chip region that is free from metallic features may be formed, and is referred to as a metal-free strip hereinafter. When a scribe line includes two dummy conductive features 52 on the opposing sides of dummy conductive features 56, there are two metal-free strips, each being on a side of the dummy conductive features 56. When viewed in the top view of wafer 2, for example, as shown in FIG. 10, the metal-free strips may be long-and-straight strips that extend throughout the whole length of the respective scribe line 6, and may extend to opposite edges of the wafer 2. In accordance with some embodiments, the opposite edges of trench 60 are vertically aligned to the metal-free strips.

Referring to the top view of wafer 2 as shown in FIG. 10, a plurality of trenches 60 are formed and interconnected as a grid. Scribe lines 6 are also interconnected as a grid, and the grid of trenches 60 are inside the grid of scribe lines 6, with the edges of trenches 60 being spaced apart from the boundaries of scribe lines 6.

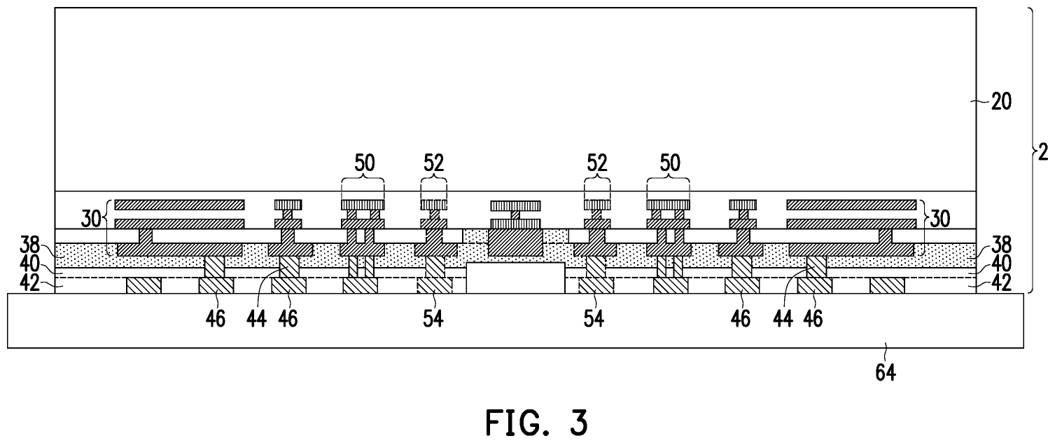

After the etching process, the etching mask 58 as shown in FIG. 2 is removed. Next, as shown in FIG. 3, the front side of wafer 2 is attached to back-grinding tape 64. A backside grinding process is then performed, so that the substrate 20 of wafer 2 is thinned. The respective process is illustrated as process 204 in the process flow 200 as shown in FIG. 11.

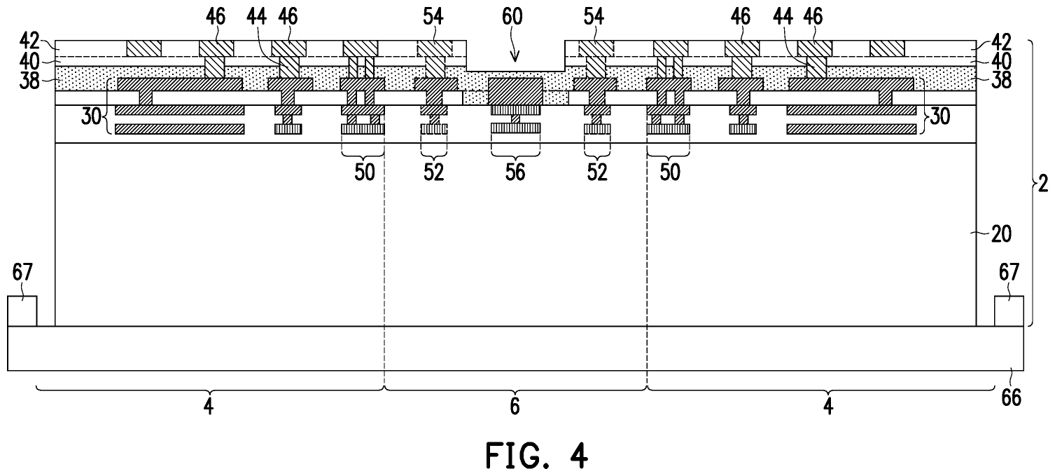

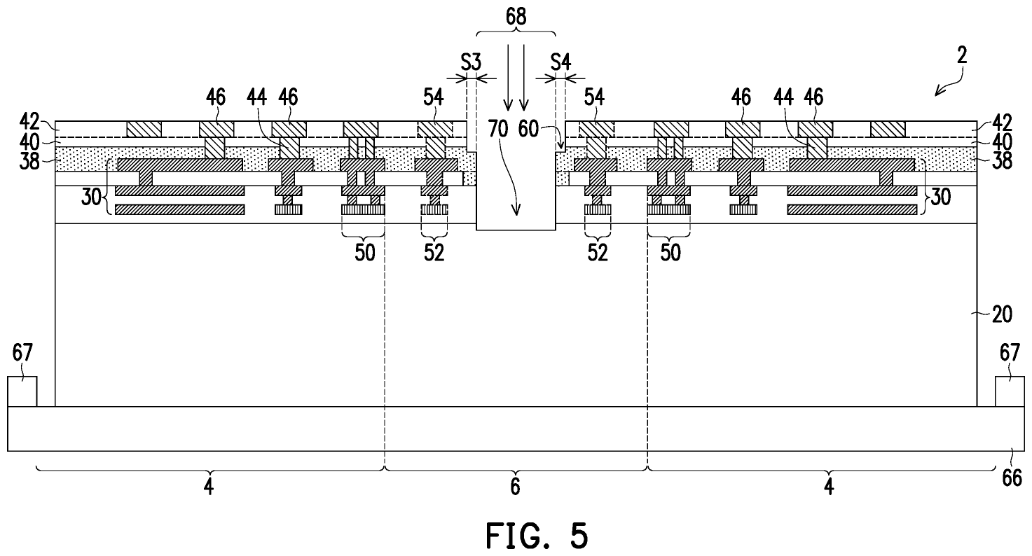

After the backside grinding process, wafer 2 is detached from back-grinding tape 64. Next, as shown in FIG. 4, the backside of wafer 2 is attached to dicing tape 66, which is fixed on frame 67. Subsequently, as shown in FIG. 5, a laser grooving process 68 is performed using a laser beam, so that trench 70 is formed to extend from the bottom of trench 60 downwardly. The respective process is illustrated as process 206 in the process flow 200 as shown in FIG. 11.

In accordance with some embodiments, the laser grooving process 68 is performed until the bottom of trench 70 at least reaches, or may extend into semiconductor substrate 20. During the laser grooving process 68, dummy conductive features 56 (FIG. 4) and the dielectric material on the path of trench 70 are removed. In accordance with some embodiments, trench 70 is in the middle of trench 60, with the opposing edges of trench 70 having equal distance S3 and S4 from their nearest edges of trench 60. In accordance with alternative embodiments, distance S3 may be different from distance S4.

In accordance with some embodiments, a plurality of trenches 70 are formed in wafer 2, each in one of scribe lines 6 and in a corresponding trench 60. In the top view of wafer 2, the trenches 70 are also interconnected as a grid. In the top view, trenches 70 are inside, and are narrower than, the corresponding trenches 60, and the edges of trenches 70 are spaced apart from the edges of trenches 60, as can also be realized from FIGS. 5 and 10.

In the laser grooving process, dummy conductive features 52, when formed, are not removed, and are laterally spaced apart from trenches 60 and 70. Laser grooving tends to cause protrusion on the top surfaces of the regions surrounding the regions that receive the laser beam. If the laser grooving is performed on the wafer 2 as shown in FIG. 1 (without having trenches 60 being formed first), after the laser grooving process, the top surfaces of the portions of wafer adjacent to the laser-burned regions may have protrusions. With the protrusions, the top surface of wafer 2 is no longer planar, which causes non-bond issues. By forming trenches 60 and performing laser grooving inside trench 60, the protrusion, if occurs, would happen inside trenches 60, and the top surface of wafer 2 that is to be bonded remains being planar.

In addition, since trench 60 is shallow, it is easy to remove the residue of etching mask 58 (such as photoresist) that is possibly left in trench 60. Otherwise, if deep trenches are formed, for example, with two deep trenches formed on opposite sides of dummy conductive features 56 and extending into substrate 20, since the deep trenches have high aspect ratios, it is difficult to remove the residues of the photoresist.

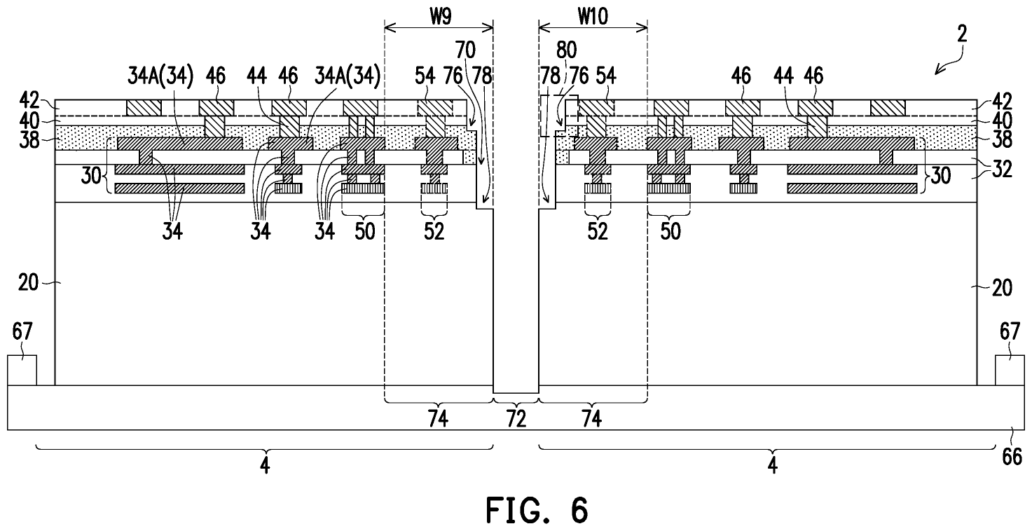

Referring to FIG. 6, wafer 2 is sawed (singulated) in a die-saw process. The respective process is illustrated as process 208 in the process flow 200 as shown in FIG. 11. The die-saw process may be performed using a blade. Cutting line 72 is thus formed. A plurality of cutting lines 72 are formed, each extending down from one of trenches 70. Wafer 2 is thus cut into a plurality of discrete device dies 4, which may be identical to each other. In accordance with some embodiments, cutting line 72 is in the middle of the respective trench 70, which means that cutting line 72 has equal distances (widths) W9 and W10 from their nearest edge of trench 70. In accordance with alternative embodiments, width W9 is different from width W10. The advantageous feature of having different widths W9 and W10 is discussed subsequently referring to FIG. 9.

As shown in FIG. 6, device dies 4, after the singulation, has a remaining portion 74 outside of seal ring 50. The remaining portion 74 includes a portion of semiconductor substrate 20, portions of the overlying dielectric layers, and may or may not include dummy conductive features 52.

In accordance with some embodiments, device die 4 includes step 76, which is formed outside of seal ring 50, and may be on the outer side of dummy conductive features 52 if they are formed. The step 76 is formed in addition to step 78, which is formed adjacent to the top surface and a sidewall of semiconductor substrate 20.

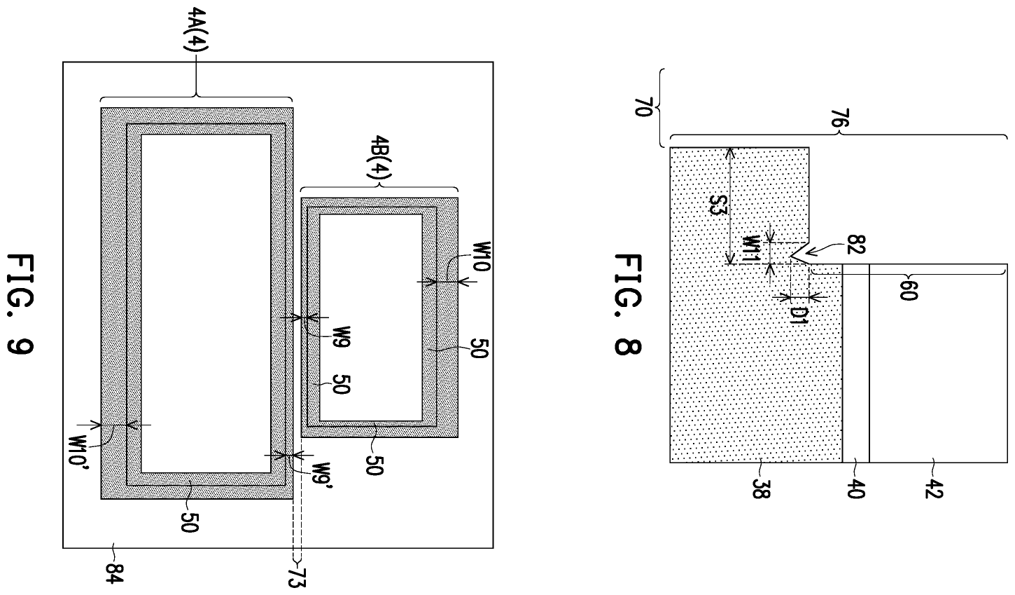

FIG. 8 illustrates a magnified view of step 76, which is formed of a sidewall of dielectric layer(s) 40/42, a top surface of dielectric layer 38, and a sidewall of dielectric layer 38. In accordance with some embodiments, the width S3 of the step 76 is greater than about 5 μm, and may be in the range between about 5 μm and about 90 μm. In addition, due to the etching process for forming trench 60, which process may adopt plasma, divot 82 may be formed at the top surface of dielectric layer 38, and is formed close to the edge of dielectric layers 42 and 40. In accordance with some embodiments, divot 82 has depth D1 greater than about 0.1 μm, and may be in the range between about 0.1 μm and about 0.5 μm. The width W11 of divot 82 may be in the range between about 0.1 μm and about 0.5 μm.

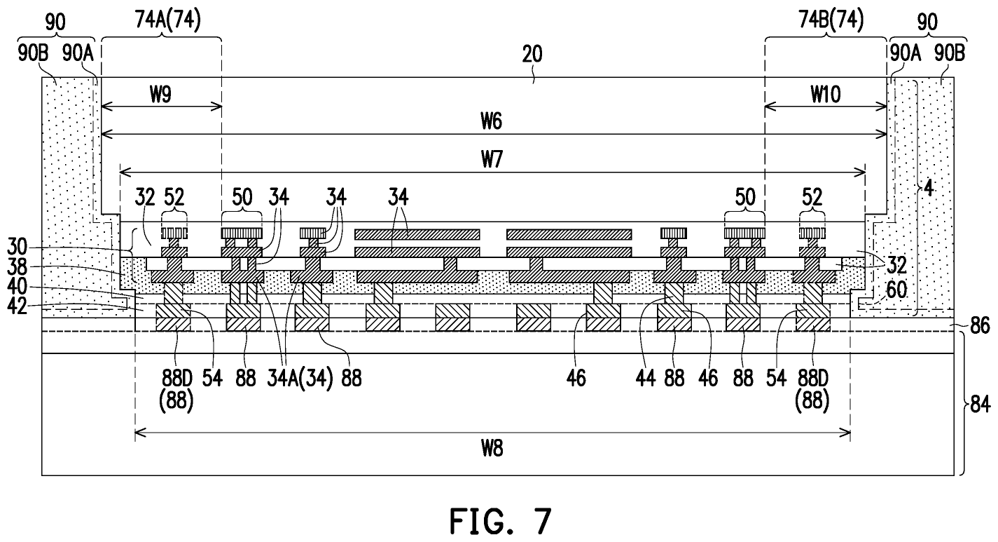

FIG. 7 illustrates the bonding of device die 4 onto package component 84 to form package 92 in accordance with some embodiments. Package component 84 may include a device die, a package including device die(s) packaged therein, an interposer, or the like. Package component 84 may include surface dielectric layer 86, and bond pads 88 in dielectric layer 86. In accordance with some embodiments, dielectric layer 86 may be formed of or comprise a silicon-containing dielectric material such as SiON, SiN, SiOCN, SiCN, SiOC, SiC, SiO₂, or the like. Bond pads 88 may include copper.

The bonding of device die 4 to the package component 84 may include hybrid bonding, which includes the bonding of dielectric layer 86 to bond film 42 through dielectric-to-dielectric bonding, and the bonding of bond pads 46 to bond pads 88 through direct metal-to-metal bonding. The dielectric-to-dielectric bonding may include fusion bonding, which includes the formation of Si—O—Si bonds. The dummy bond pads 54 of dummy conductive features 52 may be also be bonded to dummy bond pads 88D of bond pads 88. In accordance with some embodiments, before the bonding process, dummy bond pads 88D may be electrically floating. After the bonding process, the combined feature including dummy bond pads 88D and dummy bond pads 54 may be or may not be electrically floating.

Device die 4 may then be encapsulated in encapsulant 90. In accordance with some embodiments, encapsulant 90 includes a molding compound, a molding underfill, or the like. In accordance with alternative embodiments, encapsulant 90 is formed of an inorganic material(s). For example, encapsulant 90 may include adhesion layer 90A, which may be formed of or comprise silicon nitride, and dielectric region 90B, which may be formed of or comprise silicon oxide.

In accordance with some embodiments, device die 4 includes a plurality of different widths W6, W7, and W8 measured at different levels. In accordance with some embodiments, width W6 is measured at a level in semiconductor substrate 20, width W7 is measured at a level in one of dielectric layers such as dielectric layer 38, and width W8 is measured at a level in bond film 42. Due to the formation of trenches before the die-saw processes, Width W6 is greater than width W7, and width W7 is greater than width W8.

Device die 4 includes portions 74 remaining outside of seal ring 50. The remaining portion 74A on the left side of the left portion of seal ring 50 has width W9, and the remaining portion 74B on the right side of the right portion of seal ring 50 has width W10. In accordance with some embodiments, width W9 is equal to width W10. In accordance with some embodiments, due to the formation of a single trench (rather than two trenches), it is possible to allow widths W9 and W10 to have greater values. For example, widths W9 and W10 may be greater than about 1.5 μm, and may be in the range between about 1.5 μm and about 90 μm. Since the remaining portions 74 are wider with greater widths W9 and W10, if delamination occurs at cutting line 72 during the die-saw processes, for example, between the low-k dielectric layers 32, the propagation path is longer before the delamination may propagate to seal ring 50. The integrated circuit devices in the active areas of the device dies, which active areas are inside seal rings, is less likely to be adversely affected.

Also, due to the formation of a single trench (rather than two trenches), it is possible to allow width W9 to be different from width W10. The width difference |(W9−W10)| may be greater than about 1.0 μm, and may be in the range between about 1.0 μm and about 80 μm. The width difference may be generated by making spacing S1 (FIG. 2) to be different from spacing S2, and/or spacing S3 (FIG. 3) to be different from spacing S4.

In accordance with some embodiments, width W9 is different from width W10. For example, FIG. 9 illustrates an example usage of different widths W9 and W10. As shown in FIG. 9, two device dies 4 (including 4A and 4B) are bonded to the same package component 84, and are placed close to each other. The remaining portion 74 of device die 4B on the side facing toward device die 4A has width W9, which is smaller than the width W10 on the opposite side. Making width W9 being smaller is benefit for the gap-filling of encapsulating 90 (FIG. 7) when device dies 4A and 4B are tightly placed close to each other. By making width W9 to be smaller than width W10, the gap 73 between device dies 4A and 4B is wider. The gap-filling into the narrow gap 73 is thus easier, and void is less likely to be formed in the encapsulant 90.

Similarly, the remaining portion of device die 4A on the side facing toward device die 4B has width W9′, and the remaining portion of device die 4A on the side facing away device die 4B has width W10′. In accordance with some embodiments, width W9′ is smaller than width W10′, while width W9′ may also be equal to width 10′ in accordance with alternative embodiments.

In above-illustrated embodiments, some processes and features are discussed in accordance with some embodiments of the present disclosure to form a three-dimensional (3D) package. Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The embodiments of the present disclosure have some advantageous features. By forming shallow trenches in scribe lines, performing laser grooving in the shallow trenches, and then sawing the wafer, less space is needed in scribe lines for the die-saw process since a single trench, rather than two trenches, is formed in one scribe line. Accordingly, outside of the seal ring, more chip areas are left in the resulting dies, and the propagation path of delamination is longer. Delamination and cracks are less likely to propagate to seal rings. The device die is thus more reliable. Furthermore, by forming shallow trenches instead of forming deep trenches, it is easier to clean the residue inside the shallow trench.

In accordance with some embodiments of the present disclosure, a method comprises etching a portion of a wafer to form a first trench in a scribe line of the wafer, wherein the scribe line is between a first device die and a second device die of the wafer, and wherein after the etching, a top surface of the portion of wafer in the scribe line is underlying and exposed to the first trench, and the first trench is between opposing sidewalls of the wafer; performing a laser grooving process to form a second trench extending from the top surface further down into the wafer, wherein the second trench is laterally between the opposing sidewalls of the wafer; and performing a die-saw process to saw the wafer, wherein the die-saw process is performed from a bottom of the second trench, and wherein the die-saw process results in the first device die to be separated from the second device die.

In an embodiment, the scribe line has a middle line in middle of the first device die and the second device die, and wherein the first trench crosses the middle line. In an embodiment, the scribe line comprises a dummy conductive feature, and wherein the first trench overlaps the dummy conductive feature. In an embodiment, the etching is stopped before the dummy conductive feature is exposed. In an embodiment, the wafer comprises a top surface dielectric layer, and an underlying dielectric layer underlying the top surface dielectric layer, and wherein the etching stops on an additional top surface of the underlying dielectric layer. In an embodiment, the die-saw process is performed at a position closer to the first device die than the second device die.

In an embodiment, the first device die comprises a first seal ring, and the second device die comprises a second seal ring, and wherein the wafer further comprises a test conductive feature in the scribe line, and the test conductive feature is between the first seal ring and the first trench. In an embodiment, at a time when the first trench finishes formation, the scribe line has a single trench therein. In an embodiment, the etching is performed through an anisotropic etching process. In an embodiment, the second trench formed by the laser grooving process reaches a semiconductor substrate of the wafer.

In accordance with some embodiments of the present disclosure, a structure comprises a device die comprising a semiconductor substrate; a seal ring over the semiconductor substrate and encircling an active area of the device die; a first dielectric layer over the semiconductor substrate; a second dielectric layer over the first dielectric layer, wherein the second dielectric layer extends lateral beyond the first dielectric layer; and a first bond pad in the second dielectric layer. In an embodiment, the structure further comprises a package component overlying and bonding to the device die, wherein the package component comprises a second bond pad bonding to the first bond pad; and a third dielectric layer, wherein the second bond pad is in the third dielectric layer, and wherein the third dielectric layer is bonded to the second dielectric layer of the device die.

In an embodiment, the structure further comprises an encapsulant encapsulating the device die, wherein the encapsulant contacts a top surface of the first dielectric layer to form an interface. In an embodiment, a first portion of the encapsulant overlaps a second portion of the first dielectric layer. In an embodiment, the structure further comprises a test conductive feature outside of the seal ring. In an embodiment, the structure further comprises a package component overlying and bonding to the device die, wherein the test conductive feature is further bonded to an additional bond pad in the package component. In an embodiment, the device die comprises a first portion and a second portion outside of, and on opposing sides of the seal ring, wherein the first portion is narrower than the second portion.

In accordance with some embodiments of the present disclosure, a structure comprises a device die comprising a semiconductor substrate, wherein the device die has a first width measured at a first level of the semiconductor substrate; a first dielectric layer over the semiconductor substrate, wherein the device die has a second width measured at a second level of the first dielectric layer, and the second width is smaller than the first width; and a second dielectric layer over the first dielectric layer, wherein the device die has a third width measured at a third level of the second dielectric layer, and the third width is smaller than the second width; and a package component over and bonding to the device die.

In an embodiment, each of the first width, the second width, and the third width is measured from a first outmost edge of the device die to an opposing outmost edge of the device die. In an embodiment, the device die further comprises a seal ring proximate edges of the device die; and a test conductive feature outside of the seal ring, wherein the seal ring is in physical contact with the package component.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
etching a portion of a wafer to form a first trench in a scribe line of the wafer, wherein the scribe line is between a first device die and a second device die of the wafer, and wherein after the etching, a top surface of the portion of wafer in the scribe line is underlying and exposed to the first trench, and the first trench is between opposing sidewalls of the wafer;
performing a laser grooving process to form a second trench extending from the top surface further down into the wafer, wherein the second trench is laterally between the opposing sidewalls of the wafer; and
performing a die-saw process to saw the wafer, wherein the die-saw process is performed from a bottom of the second trench, and wherein the die-saw process results in the first device die to be separated from the second device die.

2. The method of claim 1, wherein the scribe line has a middle line in middle of the first device die and the second device die, and wherein the first trench crosses the middle line.

3. The method of claim 1, wherein the scribe line comprises a dummy conductive feature, and wherein the first trench overlaps the dummy conductive feature.

4. The method of claim 3, wherein the etching is stopped before the dummy conductive feature is exposed.

5. The method of claim 3, wherein the wafer comprises a top surface dielectric layer, and an underlying dielectric layer underlying the top surface dielectric layer, and wherein the etching stops on an additional top surface of the underlying dielectric layer.

6. The method of claim 1, wherein the die-saw process is performed at a position closer to the first device die than the second device die.

7. The method of claim 1, wherein the first device die comprises a first seal ring, and the second device die comprises a second seal ring, and wherein the wafer further comprises a test conductive feature in the scribe line, and the test conductive feature is between the first seal ring and the first trench.

8. The method of claim 1, wherein at a time when the first trench finishes formation, the scribe line has a single trench therein.

9. The method of claim 1, wherein the etching is performed through an anisotropic etching process.

10. The method of claim 1, wherein the second trench formed by the laser grooving process reaches a semiconductor substrate of the wafer.

11. A structure comprising:
a device die comprising:
a semiconductor substrate;
a seal ring over the semiconductor substrate and encircling an active area of the device die;
a first dielectric layer over the semiconductor substrate;
a second dielectric layer over the first dielectric layer, wherein the second dielectric layer extends lateral beyond the first dielectric layer; and
a first bond pad in the second dielectric layer.

12. The structure of claim 11 further comprising a package component overlying and bonding to the device die, wherein the package component comprises:
a second bond pad bonding to the first bond pad; and
a third dielectric layer, wherein the second bond pad is in the third dielectric layer, and wherein the third dielectric layer is bonded to the second dielectric layer of the device die.

13. The structure of claim 11 further comprising an encapsulant encapsulating the device die, wherein the encapsulant contacts a top surface of the first dielectric layer to form an interface.

14. The structure of claim 13, wherein a first portion of the encapsulant overlaps a second portion of the first dielectric layer.

15. The structure of claim 11 further comprising a test conductive feature outside of the seal ring.

16. The structure of claim 15 further comprising a package component overlying and bonding to the device die, wherein the test conductive feature is further bonded to an additional bond pad in the package component.

17. The structure of claim 11, wherein the device die comprises a first portion and a second portion outside of, and on opposing sides of the seal ring, wherein the first portion is narrower than the second portion.

18. A structure comprising:
a device die comprising:
a semiconductor substrate, wherein the device die has a first width measured at a first level of the semiconductor substrate;
a first dielectric layer over the semiconductor substrate, wherein the device die has a second width measured at a second level of the first dielectric layer, and the second width is smaller than the first width; and
a second dielectric layer over the first dielectric layer, wherein the device die has a third width measured at a third level of the second dielectric layer, and the third width is smaller than the second width; and
a package component over and bonding to the device die.

19. The structure of claim 18, wherein each of the first width, the second width, and the third width is measured from a first outmost edge of the device die to an opposing outmost edge of the device die.

20. The structure of claim 18, wherein the device die further comprises:
a seal ring proximate edges of the device die; and
a test conductive feature outside of the seal ring, wherein the seal ring is in physical contact with the package component.
